(19) United States
(12) Patent Application Publication
(10) Pub. No.: US 2026/0299156 A1
(43) Pub. Date: Oct. 1, 2026

(54) FREQUENCY SELECTION OPTIMIZATION IN LOCATING A UTILITY LINE

(71) Applicant: The Charles Machine Works, Inc., Perry, OK (US)

(72) Inventors: Jared Hoag, Stillwater, OK (US); Jordan Tyler Paul, Tulsa, OK (US); Harold G. Shoemaker, Perry, OK (US)

(21) Appl. No.: 19/577,615

(22) Filed: Mar. 25, 2026

Related U.S. Application Data
(60) Provisional application No. 63/777,449, filed on Mar. 25, 2025.

(51) Int. Cl. G01V 3/08; G01R 25/00

(52) U.S. Cl. CPC G01V 3/081; G01R 25/00

(57) ABSTRACT

A system and method for selecting a locating-signal frequency for a buried utility line. A transmitter is coupled to the utility line and applies locating signals at multiple candidate frequencies. For each frequency, the transmitter measures the waveform of a voltage and a current associated with the locating signal and determines a corresponding phase angle. A favored frequency is identified based on the phase angles, and the transmitter applies a locating signal at the favored frequency during a locating operation. In some embodiments, standing wave ratio, impedance matching, and receiver-based signal and noise detection may also be employed.

### SUMMARY

The present invention is directed to a system for locating a buried utility line, the system comprising a transmitter and a receiver. The transmitter has an output interface configured to be coupled to the buried utility line. The transmitter comprises a signal generator, a voltage-sensing circuit, and a current-sensing circuit. The signal generator is configured to apply a locating signal to the buried utility line at each of a plurality of frequencies via the output interface. The voltage-sensing circuit is configured to measure a voltage associated with the locating signal as applied to the buried utility line, and the current-sensing circuit is configured to measure a current associated with the locating signal as applied to the buried utility line.

The transmitter is configured to receive voltage measurements and current measurements from the voltage-sensing circuit and current-sensing circuit for each of the plurality of frequencies, to determine a phase angle between the measured voltage and current at each of the plurality of frequencies, and identify based on the phase angle, a favored frequency from among the plurality of frequencies. The receiver is configured to detect the locating signal having the favored frequency at an above-ground location.

In another aspect, the invention is directed to a method for selecting a locating-signal frequency for a buried utility line. The method comprises coupling a transmitter to the buried utility line, applying, by the transmitter, a locating signal to the buried utility line at each of a plurality of frequencies, and measuring, for each of the plurality of frequencies, a voltage associated with the locating signal and a current associated with the locating signal.

The method further comprises determining for each of the plurality of frequencies a phase angle between the measured voltage and measured current. Using the determined phase angles, a favored frequency is identified from among the plurality of frequencies, and a transmitter applies a locating signal having the favored frequency during a locate operation.

### BRIEF DESCRIPTION OF THE DRAWINGS

FIG. 1 is a diagrammatic representation of a locating operation, with a transmitter connected to a utility line, which emits a signal received by a receiver at an above ground location.

FIG. 2 is a graphical representation of resistance, reactance, and impedance.

FIG. 3 is a graphical representation of real power, reactive power, and apparent power.

FIG. 4 is a graphical representation of a waveform where current leads voltage.

FIG. 5 is a graphical representation of a waveform where the current lags behind the voltage.

FIG. 6 is a graphical representation of a waveform with a zero phase angle between the current and the voltage.

FIG. 7 is a graphical representation of a standing wave ratio of a signal.

FIG. 8 is a block diagram representing current-sensing and voltage-sensing circuits within a transmitter architecture for determining the phase angle of an emitted signal.

### DETAILED DESCRIPTION

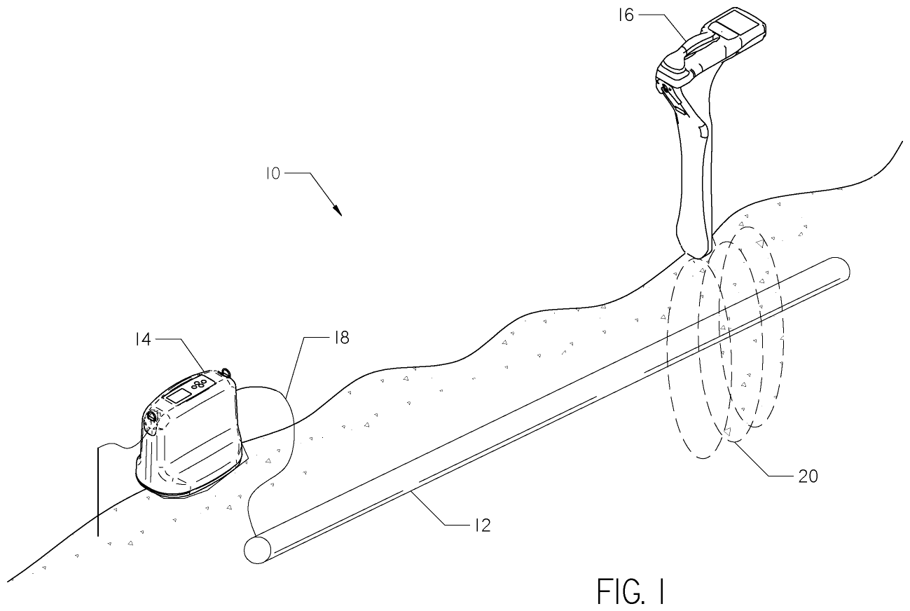

Turning to FIG. 1, shown therein is a system 10 for locating buried utility lines 12. The system 10 uses known equipment, such as a signal transmitter 14 and a signal receiver 16 (or “locator”) to conductively or inductively apply a magnetic field signal 20 to the utility line 12 so electrical current flows on it. This current produces a magnetic field 20 along the full length of the buried utility line 12. The locator 16 is used above the ground to trace the path of the buried, conductive utility line 12 and to determine its depth under that path.

Current practices for locating the buried utility line 12 include connecting the transmitter 14 via a signal output device 18, here, direct connect leads, selecting a low frequency (256 Hz-1.17 kHz), and choosing a high-power setting. However, this approach may not always yield ideal results. Several variables can affect its effectiveness, such as soil type, soil moisture, air humidity, and the material of the connected item (e.g., steel pipe versus solid copper tracer wire). Additional factors include junctions in the tracer wire or pipe, and corrosion. These variables can cause the low frequency high power method to contain inaccuracies.

In the power industry, specific conditions are sought to deliver power down a utility line as efficiently as possible. However, when applying this concept to signal transmission, a problem arises: the transmitter 14 does not “know” the characteristics of the utility line to which it is connected, and it may be difficult or impossible to determine such characteristics, as they are indicative of buried conditions. Key factors that may impact the signal transmission include inductance, capacitance, and impedance, as these affect the phase angle. The desired phase angle is zero, indicating a purely resistive line. As the phase angle approaches 90 degrees (pure inductive) or −90 degrees (pure capacitive), it becomes harder to transmit power down the utility line.

To ensure the transmitter 14 achieves a maximum and most efficient power delivery to a connected line, it is beneficial to know the phase angle. Therefore, a method is provided to detect frequencies with favorable characteristics. As an example, when the transmitter 14 is connected to the utility line 12, the transmitter 14 may sweep a frequency range, measure the voltages and the currents associated with each frequency, determine if the voltages or the currents are in phase or if one is lagging, calculate the phase angle, and then provide a user with the frequencies closest to a zero phase angle.

Locators 16 and transmitters 14 generally allow generation of, and receipt of, a signal 20 at a predefined set of frequencies. The locator 16 and the transmitter 14 may cooperate in the determination of the signal frequency to place on the buried utility line 12. One such method of selecting a preferred frequency is disclosed in U.S. Pat. No. 10,107,931, issued to Bailey (“Bailey”), the contents of which are incorporated herein by reference. Bailey provides a method of detecting ambient electromagnetic signals, which helps determine the optimal frequencies to use for locating buried utilities 12. This method is typically performed by placing the locator 16 in a noise measurement mode in which the locator 16 measures noise levels at various frequencies while the transmitter 14 is turned off. A signal-to-noise ratio is then calculated for the predefined set of frequencies and assigned a quality indicator.

An operator then chooses a frequency with a favorable quality indicator, and thereafter, places a locate signal on the buried utility line 12 with the signal transmitter 14 at the chosen frequency. However, this method does not account for the unknown characteristics of the utility line 12 discussed above. Rather, the method of Bailey only takes in information at the locator 16—that is, information about the signal and noise environments at a location where the signal 20 can be received. No direct information about the utility line 12 itself may be determined at the locator 16, as this requires a direct connection. Therefore, additional methods, utilizing the transmitter 14, are provided to overcome this obstacle.

In addition to the noise minimization step, the transmitter 14 may perform steps to determine information about phase angle and signal reflection which may tend to make a frequency less desirable. This additional set of steps, described herein, may occur alone, or in conjunction with the noise minimization step. The order of these two procedure steps does not matter—rather, information about signal-to-noise ratio may be combined with information about the utility line 12 itself such that the operator or a processor may determine the most favored transmission frequency for a particular locate operation.

In one embodiment, the receiver 16 communicates, to the transmitter 14, favorable frequencies based upon the noise minimization step. Alternatively, the transmitter 14 may perform its own analysis of frequencies without consideration of the signal-to-noise measurement and may send such information to the receiver 16 or the processor for further calculation.

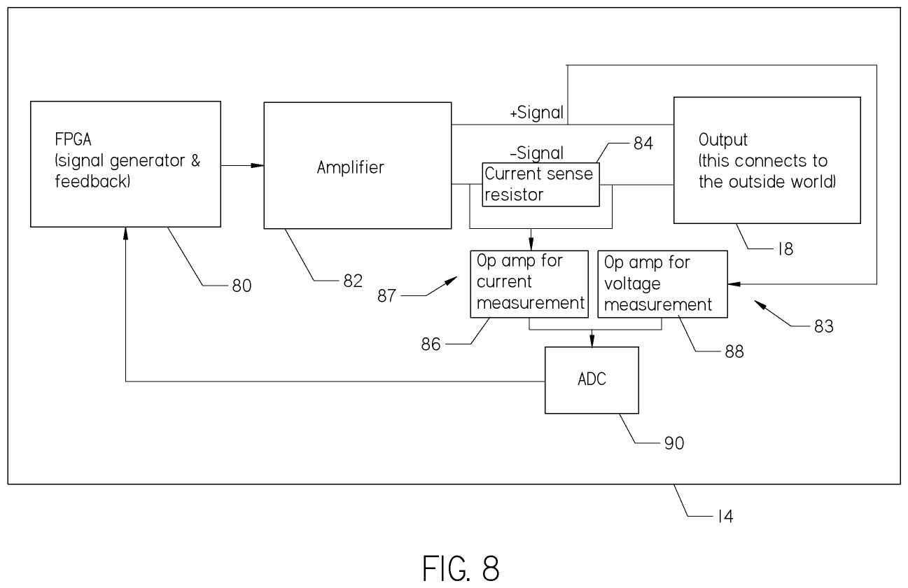

The transmitter 14 performs a quality measurement by sequentially placing a signal on the utility line 12 at each of the selected frequencies, and measuring the voltage and the current of the signal 20 on the utility line 12. In FIG. 8, a block diagram of the transmitter 14 is shown, providing structure associated with a circuit capable of detecting the current and voltage waveforms.

With reference to FIG. 8, the transmitter 14 has a set of predetermined frequencies for a frequency sweep. During the frequency sweep, a field-programmable gate array (“FPGA”) 80 begins by starting at a first frequency for the signal 20. Preferably, the FPGA 80 may begin at a lowest frequency and sweep to a highest frequency. The signal 20 is sent to an amplifier 82, which then sends the signal 20 to the signal output device 18.

Prior to the signal 20 reaching the signal output device 18, a portion of the signal 20 leaving the amplifier 82 is placed on a current-sensing circuit 83. The current-sensing circuit 83 may include a current-sensing resistor 84. A first operational amplifier 86 is connected to the current-sensing resistor 84 and determines waveform information about a current. Formats suitable for detecting a current may be utilized as a current sensing circuit 83. Likewise, a voltage-sensing circuit 87 may include a second operational amplifier 88 configured to detect the voltage waveform information. Alternative voltage-sensing circuits 87 may be utilized as well.

The detected voltage waveform is sent from the voltage-sensing circuit 87 to an analog-to-digital converter (“ADC”) 90. The detected current waveform is sent from the current-sensing circuit 83 to the analog-to-digital converter 90. A signal is then returned to the FPGA 80. The FPGA 80 will store the frequencies that were close to or equal to zero.

As discussed above, the transmitter 14 may send a message to the receiver 16 that the frequency sweep is complete and there are a plurality of frequencies that the transmitter 14 prefers. The receiver 16 may subsequently perform methods to determine a signal-to-noise ratio and choose the best frequency for use by the transmitter 14. The receiver 16, or the associated processor, would then poll these frequencies to determine which is best for both the receiver 16 and the transmitter 14.

This additional information may be communicated to the operator or processor, and a frequency for the locate operation may be selected based on both the conditions of the line and the environmental noise. Communication between the receiver 16 and the transmitter 14 may be conducted through Bluetooth® communication protocols. Alternatively, wireless communication between the receiver 16 and the transmitter 14 may be performed by LoRa® sub-gigahertz radio frequency communication. LoRa® frequencies, and other sub-gigahertz frequencies, may be preferable, because while data transfer rates are decreased, the lower frequency wireless transmission has greater effective range.

Alternatively, the transmitter 14 may simply provide a display of preferred frequencies for operator information and instruction.

While the FPGA 80 provides a simple way of storing preferred frequencies, an artisan can appreciate that the ADC 90 may output information to the processor or controller, either locally within the transmitter 14, or external thereto.

In an alternating current (“AC”) circuit, “voltage versus current phase” refers to the timing difference between the voltage waveform and the current waveform, essentially describing whether the voltage reaches its peak before, after, or at the same time as the current, measured in degrees as the phase angle. If the voltage or the current reach their peaks at the same time, they are considered “in phase”. If the voltage leads the current, the voltage is considered “leading”. If the current leads the voltage, the voltage is considered “lagging”. While either the current or the voltage may be “leading” or “lagging” in waveform, for the purposes of this disclosure, a “leading” waveform indicates that the voltage is “leading”.

Thus, the transmitter 14 outputs a known signal 20 at a known frequency on the utility line 12. The utility line 12 presents a load with unknown characteristics. The resulting waveforms of the voltage and the current provide information about the characteristics of the utility line 12, allowing the phase angle to be computed. When the voltage and the current waveforms reach their peak values simultaneously, they are said to be “in phase”, which usually occurs in a purely resistive circuit.

The phase angle between the voltage and the current is important because it affects the power factor in an AC circuit. A significant phase difference indicates a low power factor, meaning less power is efficiently transferred through the circuit. Capacitance and inductance can introduce phase shifts between the voltage and the current, causing the voltage to lead or lag the current depending on the circuit configuration.

Apparent power of a source has both real and reactive power. Real power represents the actual power consumed for useful work (transmitting a signal), reactive power is the result from inductive or capacitive load, and does not provide any useful work. The source must produce both components for the AC circuit.

$${P}_{a} = \sqrt{{P}_{r}^{2} + {P}_{v}^{2}}$$

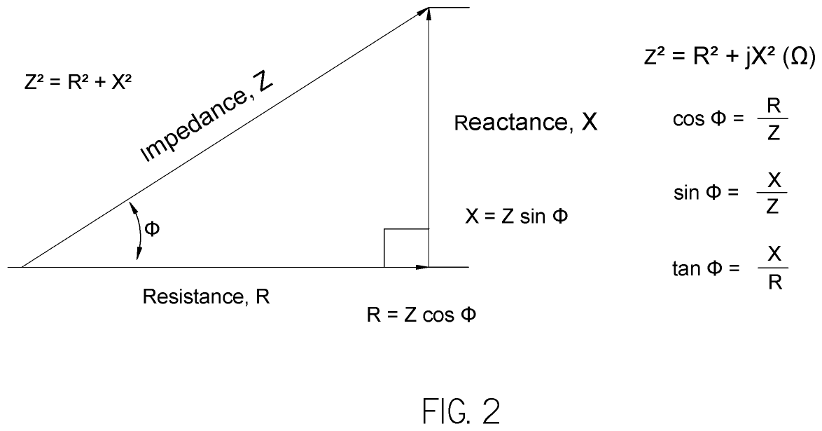

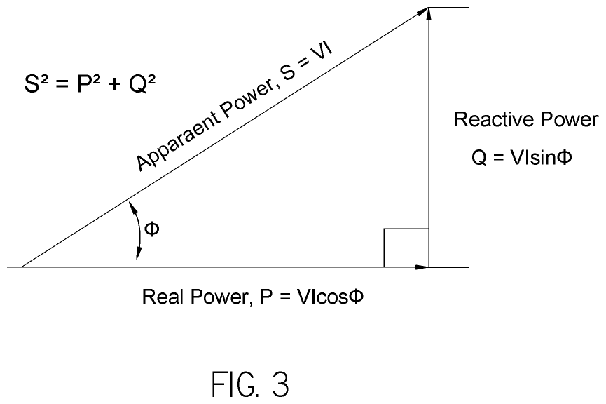

With reference now to FIGS. 2 and 3, electrical power consumed in the AC circuit can be represented by the three sides of a right-angle triangle.

Resistance (R) and Reactance (X) can be represented as a single component Impedance (Z), where Z is the hypotenuse of the right triangle shown in FIG. 2, and is equal to the sum of the squares of R and X.

As shown in FIG. 3, Real Power (P) and Reactive Power (Q) can be represented as a single component, Apparent Power(S). With a constant Apparent Power(S) produced by the Source, any Reactive Power (Q) will result in lower Real Power (P).

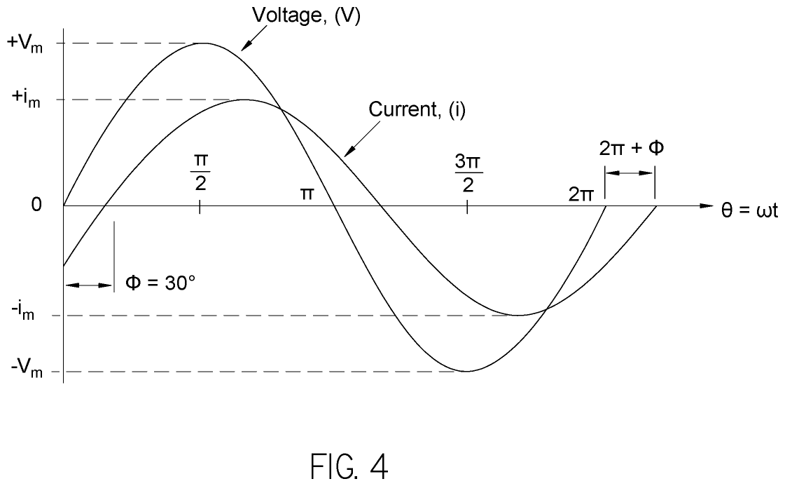

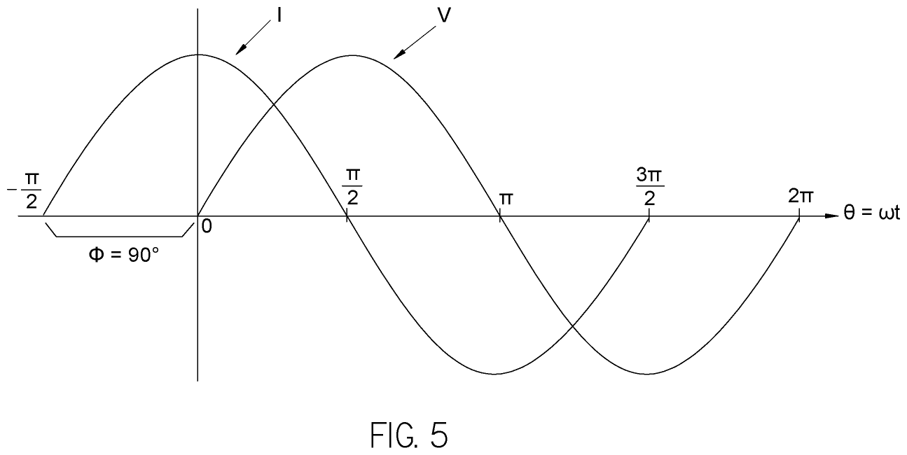

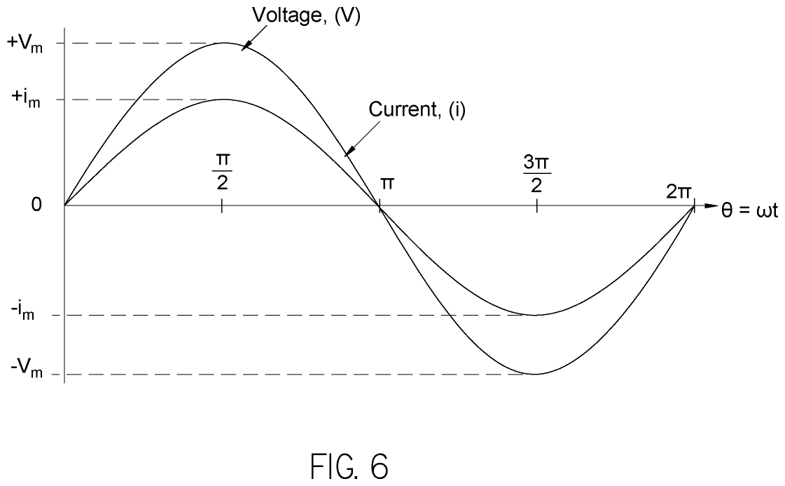

FIGS. 4-6 show various phase angles and how those phase angles tend to create inductive and capacitive reactance. The phase angle between the voltage and the current is important because it affects the power factor in the AC circuit. A significant phase difference indicates a low power factor, meaning less power is efficiently transferred through the circuit. FIGS. 4-6 show the conditions of inductive, capacitive, and pure resistive lines. In FIG. 4, this represents the utility line 12 being inductive. In FIG. 5, this represents the utility line 12 being capacitive. In FIG. 6, the utility line 12 is in phase and purely resistive.

Formula for inductive reactance: X_L=2πfL, where X_L is the inductive reactance, f is the frequency of the AC current, and L is the inductance of the inductor.

Formula for capacitive reactance: When voltage lags current, which occurs in a capacitive circuit, the formula for calculating the capacitive reactance (XC) is: XC=1/(2πfC), where “f” is the frequency, and “C” is the capacitance.

When voltage and current are “in phase,” they reach their peak values at the same time in an AC circuit, the basic formula to calculate the power is simply: P=V*I, where “P” is power, “V” is voltage, and “I” is current; essentially, this is just Ohm's Law applied to AC circuits with a power factor of 1 (perfectly in phase). In AC circuits, components like capacitors and inductors can cause the voltage and the current to be out of phase, which is accounted for by the “power factor” (PF) in the formula: P=V*I*PF.

Thus, with the waveform detected and the power factors determined for each frequency transmitted at the transmitter 14, the quality of a particular frequency for optimizing phase angle is determined and considered in the ultimate selection of a frequency for a locating operation.

In addition to phase angle, to optimize the power delivery from the transmitter 14 to the connected utility line 12, it is preferable to know the Standing Wave Ratio (“SWR”). The Standing Wave Ratio is a measurement used in radio frequency systems to determine how efficiently power is being transmitted from the transmitter 14 to a load. It indicates a ratio of a maximum to a minimum voltage along a transmission line.

A 1:1 SWR is the ideal condition where all the power is transmitted to the load with no reflections. It indicates a perfect impedance match between the transmission line and the load. If the SWR is greater than 1:1, there is an indication that some power is being reflected back towards the transmitter 14 due to an impedance mismatch. The higher the SWR, the greater the mismatch and the power being reflected.

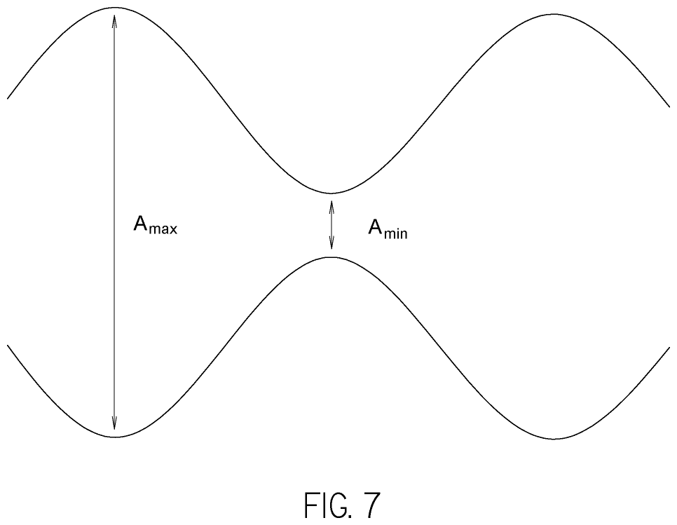

SWR can be calculated using the maximum and minimum voltages along the transmission line:

$$SWR = {A}_{max} / {A}_{min}$$

where:
Aₘₐₓ is the maximum voltage along the transmission line.
Aₘᵢₙ is the minimum voltage along the transmission line. A graphical representation of SWR is shown in FIG. 7.

Using the Reflection Coefficient, SWR can also be calculated using the reflection coefficient:

$$SWR = \frac{1 + Γ}{1 - Γ}$$

where Γ is calculated as:

$$Γ = \frac{Z\_L - Z\_O}{Z\_L + Z\_O}$$

Z_L is the load impedance.
Z_o is the characteristic impedance of the transmission line.

### Example Calculation

This is an example to illustrate the calculation of Standing Wave Ratio.

### 1. Calculate the Reflection Coefficient:

Suppose there is a transmission line with a characteristic impedance (Z_o) of 50 ohms, and a load impedance (Z_L) of 75 ohms.

$$Γ = ( 75 - 50 ) / ( 75 + 50 ) = 0.2$$

### 2. Calculate the SWR:

Using the Reflection Coefficient:

$$SWR = ( 1 + 0.2 ) / ( 1 - 0.2 ) = 1.5$$

The SWR in this example is 1.5:1, indicating a reasonably good impedance match.

### 3. Calculate the Percentage of Power Reflection:

$$\% Refl . = \frac{{( SWR - 1 )}^{2}}{{( SWR + 1 )}^{2}} * 100$$

$$\% Refl . = ( 1.5 - 1 ) \hat{} 2 / ( 1.5 + 1 ) \hat{} 2 * 100 = 4 \%$$

The power reflection percentage is 4% in this example, indicating that 96% of power is transmitted.

In a preferred embodiment, once the transmitter 14 completes a frequency sweep and the best frequency is selected with a high quality indicator and close to zero phase angle, the SWR is calculated for the selected frequency. Knowing the SWR allows for the ability to impedance match the utility line 12. One way in which this can be accomplished is by switching taps of a balun, adjusting the impedance ratio. Once the impedance matching is complete, and power reflection percentage is optimized, the operator may proceed with the locate operation.

Therefore, a frequency can be selected according to the following method. A technician powers the transmitter 14 on and connects the transmitter 14 to the utility line 12. The transmitter 14 completes a frequency sweep, which can be initiated automatically or manually, giving the technician the top frequencies closest to a zero phase angle.

The standing wave ratio and power reflection are then calculated by the processor, enabling the impedance of the transmitter 14 to match to the utility line 12.

Thus, this disclosure provides a method for improving the identification of a frequency for induction of a locating signal on a buried utility line, by considering how characteristics of such a line impacts the overall power delivery.

The various features and alternative details of construction of the apparatuses described herein for the practice of the present technology will readily occur to the skilled artisan in view of the foregoing discussion, and it is to be understood that even though numerous characteristics and advantages of various embodiments of the present technology have been set forth in the foregoing description, together with details of the structure and function of various embodiments of the technology, this detailed description is illustrative only, and changes may be made in detail, especially in matters of structure and arrangements of parts within the principals of the present technology to the full extent indicated by the broad general meaning of the terms in which the appended claims are expressed.

1. A method for selecting a locating-signal frequency for a buried utility line, the method comprising:
coupling a transmitter to the buried utility line;
applying, by the transmitter, a locating signal to the buried utility line at each of a plurality of frequencies;
measuring, for each of the plurality of frequencies, a voltage associated with the locating signal, and a current associated with the locating signal;
determining, for each of the plurality of frequencies, a phase angle between the measured voltage and the measured current;
using the determined phase angles, identifying, from among the plurality of frequencies, a favored frequency; and
applying, by the transmitter, a locating signal having the favored frequency during a locating operation.

2. The method of claim 1, further comprising determining a standing wave ratio at the favored frequency.

3. The method of claim 2, further comprising adjusting an output impedance of the transmitter based at least in part upon the standing wave ratio.

4. The method of claim 3, further comprising adjusting the output impedance by switching taps on a balun of the transmitter.

5. The method of claim 1, further comprising detecting, with a receiver, the locating signal at an above-ground location.

6. The method of claim 5, further comprising determining, with the detected signal at the receiver, a depth of the buried utility line relative to a ground surface.

7. The method of claim 1, wherein identifying the favored frequency comprises selecting a frequency with a corresponding phase angle with a magnitude closest to zero among the plurality of frequencies.

8. The method of claim 1, wherein measuring the current associated with the locating signal comprises:
sensing a voltage across a current-sensing resistor disposed in series between an output of the transmitter and the buried utility line; and
determining the current based at least in part on the sensed voltage.

9. The method of claim 1, wherein measuring the voltage associated with the locating signal comprises using a voltage-sensing circuit configured to sense a voltage between the output of the transmitter and a reference potential.

10. The method of claim 1, wherein measuring the voltage and the current comprises:
converting analog voltage and current signals to digital values using at least one analog-to-digital converter; and
providing the digital values to a controller configured to determine the phase angle between the voltage and the current.

11. The method of claim 1, further comprising:
at a receiver, determining, at the plurality of frequencies, a signal-to-noise ratio;
wherein the step of identifying favored frequency further comprises using the determined signal-to-noise ratio.

12. The method of claim 11, further comprising communicating information regarding the plurality of candidate frequencies between the receiver and the transmitter.

13. The method of claim 12, wherein the step of communicating information between the receiver and the transmitter comprises using a sub gigahertz radio transmission.

14. A system for locating a buried utility line, the system comprising:
a transmitter having an output interface configured to be coupled to the buried utility line, the transmitter comprising:
a signal generator configured to apply a locating signal to the buried utility line at each of a plurality of candidate frequencies via the output interface;
a voltage-sensing circuit configured to measure a voltage associated with the locating signal as applied to the buried utility line; and
a current-sensing circuit configured to measure a current associated with the locating signal as applied to the buried utility line;
wherein the transmitter is configured to:
receive voltage measurements from the voltage-sensing circuit, and current measurements from the current-sensing circuit for each of the plurality of frequencies;
determine, for each of the plurality of frequencies, a phase angle between the measured voltage and the measured current; and
identify, based on the determined phase angles, a favored frequency from among the plurality of frequencies; and
a receiver configured to detect the locating signal having the favored frequency at an above-ground location.

15. The system of claim 14, wherein the receiver is further configured to determine, based on the detected locating signal, a depth of the buried utility line relative to a ground surface.

16. The system of claim 14, in which the plurality of frequencies are characterized as a first plurality of frequencies, wherein the receiver is configured to:
determine, at a second plurality of frequencies, a signal-to-noise ratio associated with each frequency of the second plurality of frequencies.

17. The system of claim 16, in which the first plurality of frequencies and the second plurality of frequencies are identical.

18. The system of claim 14, wherein the receiver and the transmitter are configured to communicate at a sub-gigahertz radio frequency.

19. The system of claim 14, further comprising a processor configured to identify the favored frequency.

20. The system of claim 14 wherein the current-sensing circuit comprises a resistor and an operational amplifier.
